(19) United States
(12) Patent Application Publication
(10) Pub. No.: US 2026/0267347 A1
(43) Pub. Date: Sep. 10, 2026

(54) APPARATUS AND METHOD FOR ACTION-LEVEL PLANNING OF COAL MINE ROBOT BASED ON DIGITAL COUSIN AND MR

(71) Applicant: Taiyuan University of Technology, Taiyuan (CN)

(72) Inventors: Shuguang LIU, Taiyuan (CN); Xuewen WANG, Taiyuan (CN); Jiacheng XIE, Taiyuan (CN); Lang QIN, Taiyuan (CN); Yali LIU, Taiyuan (CN); Rui DU, Taiyuan (CN); Zhijie XIAO, Taiyuan (CN); Xiaojun QIAO, Taiyuan (CN); Yiwen WANG, Taiyuan (CN); Jiayi ZHAO, Taiyuan (CN)

(73) Assignee: Taiyuan University of Technology, Taiyuan (CN)

(21) Appl. No.: 19/281,817

(22) Filed: Jul. 28, 2025

(30) Foreign Application Priority Data
Mar. 4, 2025 (CN) 202510251811.7

(51) Int. Cl. G05D 1/644; G05D 1/224; G05D 1/2285; G05D 1/24; G05D 1/689; G05D 101/15; G05D 105/80; G05D 107/70; G05D 109/10; G05D 111/10; G06T 7/70; G06T 19/00

(52) U.S. Cl. CPC G05D 1/6445; G05D 1/2245; G05D 1/2285; G05D 1/24; G05D 1/6895; G06T 7/70; G06T 19/006; G05D 2101/15; G05D 2105/80; G05D 2107/73; G05D 2109/10; G05D 2111/10; G06T 2207/10028; G06T 2207/30252

(57) ABSTRACT

Provided are an apparatus and method for action-level planning of a coal mine robot based on digital cousin and MR. An information data acquisition module acquires scene information data; a digital cousin scene information determining module determines digital cousin scene information; an action data determining module inputs the digital cousin scene information into an imitation learning model to obtain action data; an action pre-planning module determines an action pre-planning result according to the action data; an adjusting module adjusts the action pre-planning result by a multimodal interaction method to obtain an adjusted planning result; a spatiotemporal deduction module processes the adjusted planning result by a preset action planning algorithm and performs spatiotemporal deduction according to time dimension to obtain a spatiotemporal deduction result; and an action planning module determines an action planning result according to the spatiotemporal deduction result.

### CROSS-REFERENCE TO THE RELATED APPLICATIONS

This application is based upon and claims priority to Chinese Patent Application No 202510251811.7, filed on Mar. 4, 2025, the entire contents of which are incorporated herein by reference.

### TECHNICAL FIELD

The present disclosure relates to the field of human-robot mixed augmented intelligence technology, and in particular to an apparatus and method for action-level planning of a coal mine robot based on digital cousin and MR (Mixed Reality).

### BACKGROUND

At present, the research and development as well as application of coal mine robots has become an important part of the intelligent construction of coal mines. The original intention of the application of the coal mine robots is to achieve “robots replacement for human workers”. However, with the deepening of research and development as well as application, due to the limitation of intelligence level, the coal mine robots can only complete tasks independently in a few simple scenes, and in more cases, the deep participation of coal mine operators is still required to collaborate with the coal mine robots to complete the operational task.

The work process of the coal mine robot can be divided into three phases: perception, decision-making and execution. Decision-making is the link between perception information and actual action, and is the core factor that determines the work quality of the coal mine robot. According to the principle from macro to micro, the operational objective of the coal mine robot can be divided into three levels: task level, behavior level and action level. The action level planning is an important link in decision-making process, which can refine high-level task objective into specific action instructions to ensure that the coal mine robot can execute accurately according to established task requirements.

At present, a base-robotic arm collaborative robot is mostly used in underground coal mine, while the action planning solutions of the existing coal mine robots are all planning for the movement path of the robot or the trajectory of the robotic arm alone, and do not consider the robot base and the robotic arm as a whole for joint planning, leading to low action planning efficiency and poor adaptability.

The vast majority of action planning solutions for coal mine robots rely solely on algorithmic calculations, lack spatiotemporal reasoning capabilities, cannot be pre-executed in a virtual environment, and lack intuitive visualization of the planning results. As a result, such action planning solutions can not consider complex spatiotemporal relationships during planning, and rapidly verify the feasibility and effectiveness of action planning results.

At present, the action planning of the coal mine robot based on digital twin extends the planning process to virtual space, but the establishment of a digital twin environment depends on high-precision modeling, a large number of sensors and accurate data updated in real time, leading to long cycle and high cost, and inability to provide good cross-domain generalization ability.

Due to the dynamics and complexity of underground environment and tasks, human-robot collaboration is the main running mode of the current coal mine robots. However, under the background of human-robot collaboration, the existing action planning methods of the coal mine robot do not take into account human involvement in the action planning of the coal mine robot in the human-robot collaboration running mode. In other fields except coal mine, the human involvement is introduced in the action planning of the robots in some technical solutions, but only limited to defining motion targets or providing solutions completely independent of autonomous planning of the robots, failing to make full use of the advantages of human flexibility in intervention and adjustment and effectively combine machine intelligence with human intelligence.

Therefore, how to improve the action planning efficiency and adaptability is crucial.

### SUMMARY

An objective of the present disclosure is to provide an apparatus and method for action-level planning of a coal mine robot based on digital cousin and MR, which can improve the action planning efficiency and adaptability.

To achieve the objectives above, the present disclosure employs the following technical solution:

In a first aspect, the present disclosure provides an apparatus for action-level planning of a coal mine robot based on a digital cousin and MR, including:
an information data acquisition module, configured to acquire scene information data, where the scene information data includes single-frame red, green, and blue (RGB) images collected from an underground coal mine;
a digital cousin scene information determining module, connected to the information data acquisition module, and configured to determine digital cousin scene information, where the digital cousin scene information is determined according to the scene information data based on a 3D asset library virtual model, and the 3D asset library virtual model is a preset model library which covers operational objects, operational tools, a terrain structure, mechanical devices and auxiliary devices, and faces an operation task of the underground coal mine;
an action data determining module, connected to the digital cousin scene information determining module, and configured to input the digital cousin scene information to an imitation learning model to obtain action data, where the action data includes motion pose information of a coal mine robot, and operation pose information of a robotic arm, the imitation learning model is obtained by performing simulation training and zero-shot transfer based on a coal mine robot behavior model, the coal mine robot behavior model is obtained by performing reinforcement learning and simulation training on the coal mine robot model, and the coal mine robot model is a physical model constructed by a three-dimensional (3D) modeling tool based on entity parameters of the coal mine robot, where the entity parameters include: a size proportion, structure data and shape data;
an action pre-planning module, connected to the action data determining module, and configured to determine an action pre-planning result according to the action data;
an adjusting module, connected to the action pre-planning module, and configured to adjust the action pre-planning result by a multimodal interaction method to obtain an adjusted planning result;
a spatiotemporal deduction module, connected to the adjusting module, and configured to process the adjusted planning result by a preset action planning algorithm, and perform spatiotemporal deduction according to a time dimension to obtain a spatiotemporal deduction result, where the spatiotemporal deduction result includes a movement path of the coal mine robot and a movement trajectory of the robotic arm; and
an action planning module, connected to the spatiotemporal deduction module, and configured to determine an action planning result according to the spatiotemporal deduction result, where the action planning result includes position coordinates, pose information, and path points.

In a second aspect, the present disclosure provides a method for action-level planning of a coal mine robot based on digital cousin and MR. The method for action-level planning of a coal mine robot based on digital cousin and MR is implemented using the apparatus for action-level planning of a coal mine robot based on digital cousin and MR above, and includes the following steps:
acquiring scene information data, where the scene information data includes single-frame RGB images collected from an underground coal mine;
determining digital cousin scene information, where the digital cousin scene information is determined according to the scene information data based on a 3D asset library virtual model, and the 3D asset library virtual model is a preset model library which covers operational objects, operational tools, a terrain structure, mechanical devices and auxiliary devices, and faces an operation task of the underground coal mine;
inputting the digital cousin scene information to an imitation learning model to obtain action data, where the action data includes motion pose information of a coal mine robot, and operation pose information of a robotic arm, the imitation learning model is obtained by performing simulation training and zero-shot transfer based on a coal mine robot behavior model, the coal mine robot behavior model is obtained by performing reinforcement learning and simulation training on the coal mine robot model, and the coal mine robot model is a physical model constructed by a 3D modeling tool based on entity parameters of the coal mine robot, where the entity parameters include: a size proportion, structure data and shape data;
determining an action pre-planning result according to the action data;
adjusting the action pre-planning result by a multimodal interaction method to obtain an adjusted planning result;
processing the adjusted planning result by a preset action planning algorithm, and performing spatiotemporal deduction according to a time dimension to obtain a spatiotemporal deduction result, where the spatiotemporal deduction result includes a movement path of the coal mine robot and a movement trajectory of the robotic arm; and
determining an action planning result according to the spatiotemporal deduction result, where the action planning result includes position coordinates, pose information, and path points.

According to specific embodiments of the present disclosure, the present disclosure has the following technical effects:

The present disclosure provides an apparatus and method for action-level planning of a coal mine robot based on digital cousin and MR. A digital cousin scene is determined, and then after performing reinforcement learning and simulation training as well as simulation training and zero-shot transfer, the obtained imitation learning model is configured to generate an action pre-planning result. The pre-planning result is further adjusted through multimodal interaction, and then spatiotemporal deduction and pre-execution are carried out to generate a final action planning result, i.e., an action planning result, to make the coal mine robot execute the operation. By adjusting and deducing the pre-planning result, the generalization ability of action planning is improved, and based on the imitation learning model, a better planning result with both machine intelligence and human intelligence can be obtained. Thus, the action planning efficiency and adaptability can be improved.

### BRIEF DESCRIPTION OF THE DRAWINGS

To describe the technical solutions in the embodiments or the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a structural diagram of an apparatus for action-level planning of a coal mine robot based on digital cousin and MR;

FIG. 2 is a flowchart of an action pre-planning phase of a coal mine robot based on digital cousin;

FIG. 3 is a schematic diagram of the generation and understanding of a digital cousin scene in Step S1;

FIG. 4 is a schematic diagram of integration of a predefined behavior and a reinforcement learning model for a coal mine robot in Step S2;

FIG. 5 is a schematic diagram of imitation learning and zero-shot transfer in Step S3;

FIG. 6 is a flowchart of an action tuning phase of a coal mine robot based on mixed reality;

FIG. 7 is a schematic diagram of the presentation of an action pre-planning result in Step S5;

FIG. 8 is a schematic diagram of planning result adjustment based on multimodal interaction in Step S6;

FIG. 9 is a schematic diagram of spatiotemporal deduction and pre-execution in Step S7.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

In the related art, “an improved method for path planning of a coal mine search-and-rescue robot based on A* algorithm” is provided, the path is ultimately optimized by optimizing the neighborhood search method, expanding the search range, adjusting weights of the heuristic function, applying B-spline to smooth the path, and introducing the D algorithm. In “a method and apparatus for motion planning of a robotic arm on a coal mine autonomous inspection platform”, a movement operation of the robotic arm in a complex scene is planned in real time by performing voxelization processing on obstacles and combining a pre-training motion planner based on a Q-neural network.

The above two solutions separately provide the action planning methods of a coal mine robot base and a robotic arm carried thereon, but most of the current coal mine robots are in the form of base-robotic arm collaboration, and thus the above two solutions are difficult to meet the complete requirements of action planning thereof. In addition, both solutions are based on algorithmic calculation, and cannot be combined with the spatiotemporal deduction ability of a virtual space, making the ability to deal with complex and dynamic scenes insufficient.

In the related art, “a digital twin system of a multi-functional quadruped robot for an underground coal mine and a running method thereof” is provided. The digital twin system includes a robot virtual planning subsystem for path planning of the robot and synchronizing a result to an autonomous control module of the robot to complete walking according to a planned path result.

Although the path planning of the coal mine robot is transferred from a physical space to a virtual space by using a digital twin technology, the factors of human are not considered. Under the condition of human-robot coexistence, the decision-making ability of the human can play a vital role and should be fully utilized. In addition, in view of the fact that the virtual space based on the digital twin technology has high construction cost and weak generalization ability, it may not be applied to a new environment or condition.

In the related art, “a human-robot collaborative motion planning method and system of a mobile assembly robot” is provided. In each control cycle, a load type and pose information can be acquired by identifying a positioning device, and the motion of the assembly robot is reasonably allocated and an assembly motion trajectory of an end effector is planned according to the load information.

Although the human involvement is introduced in the motion planning of the mobile assembly robot, the motion of the robot is still completed by motion allocation and trajectory planning algorithms, and in this process, the primary role of human is to define the position and orientation of the end effector of the robotic arm, without actively participating in the detailed planning of the motion of the robot.

In the related art, “a human-robot collaborative path planning method of a mobile robot under a nonstructural environment” is provided, a path planned by an operator and a path autonomously planned by a robot are subjected to hybrid filtering and synthesis to form path planning of human-in-the-loop.

However, the autonomous planning of the robot and the path planning of the operator are simultaneous and independent, which fails to make full use of the global computing advantages of the robot and the intuitive determination ability of the operator. A more ideal way is to obtain an initial optimal solution through the computing power or the robot, and then to make flexible changes and fine adjustments by the operator with rich intuition and experience.

Digital cousin is a new concept put forward by Professor Li Feifei of Stanford University in the United States, which not only retains the advantages of digital twin, but also greatly reduces the generation cost from real to simulated environment and improves the generalization ability of learning. While the mixed reality technology can be used as an interface for human to deeply participate in action planning of the robot, thus achieving the organic integration of machine intelligence and human intelligence in the action planning of the robot. By combining the digital cousin concept and the mixed reality (MR) technology, it is expected to provide a new mode for action-level planning of the coal mine operation robot.

In order to make the objectives, features and advantages of the present disclosure more clearly, the present disclosure is further described in detail below with reference to the accompanying drawings and specific embodiments.

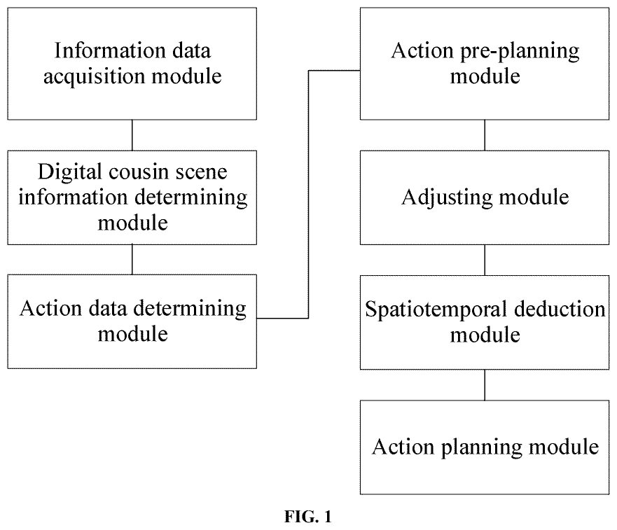

In an exemplary embodiment, as shown in FIG. 1, an apparatus for action-level planning of a coal mine robot based on digital cousin and MR is provided. The apparatus for action-level planning of a coal mine robot based on digital cousin and MR includes an information data acquisition module, a digital cousin scene information determining module, an action data determining module, an action pre-planning module, an adjusting module, a spatiotemporal deduction module, and an action planning module.

The information data acquisition module is configured to acquire scene information data, where the scene information data includes single-frame RGB images collected from an underground coal mine.

The digital cousin scene information determining module is connected to the information data acquisition module, and configured to determine digital cousin scene information, where the digital cousin scene information is determined according to the scene information data based on a 3D asset library virtual model, and the 3D asset library virtual model is a preset model library which covers operational objects, operational tools, a terrain structure, mechanical devices and auxiliary devices, and faces an operation task of the underground coal mine.

The action data determining module is connected to the digital cousin scene information determining module, and configured to input the digital cousin scene information to an imitation learning model to obtain action data, where the action data includes motion pose information of a coal mine robot, and operation pose information of a robotic arm, the imitation learning model is obtained by performing simulation training and zero-shot transfer based on a coal mine robot behavior model, the coal mine robot behavior model is obtained by performing reinforcement learning and simulation training on the coal mine robot model, and the coal mine robot model is a physical model constructed by a 3D modeling tool based on entity parameters of the coal mine robot, where the entity parameters include: a size proportion, structure data and shape data.

The action pre-planning module is connected to the action data determining module, and configured to determine an action pre-planning result according to the action data.

The adjusting module is connected to the action pre-planning module, and configured to adjust the action pre-planning result by a multimodal interaction method to obtain an adjusted planning result.

The spatiotemporal deduction module is connected to the adjusting module, and configured to process the adjusted planning result by a preset action planning algorithm, and perform spatiotemporal deduction according to a time dimension to obtain a spatiotemporal deduction result, where the spatiotemporal deduction result includes a movement path of the coal mine robot and a movement trajectory of the robotic arm.

The action planning module is connected to the spatiotemporal deduction module, and configured to determine an action planning result according to the spatiotemporal deduction result, where the action planning result includes position coordinates, pose information, and path points.

In an embodiment, the digital cousin scene information determining module includes a semantic segmentation submodule, a label annotation submodule, a point cloud data determining submodule, a semantic similarity determining submodule, a scene construction submodule, and a matching submodule.

The semantic segmentation submodule is connected to the information data acquisition module, and configured to perform semantic segmentation on the scene information data to obtain segmented information data.

The label annotation submodule is connected to the semantic segmentation submodule, and configured to perform object label annotation on the segmented information data by a large language model to obtain annotation information.

The point cloud data determining submodule is connected to the label annotation submodule, and configured to determine point cloud data according to the annotation information, where the point cloud data includes three-dimensional position information.

The semantic similarity determining submodule is connected to the point cloud data determining submodule, and configured to determine semantic similarity according to the annotation information and the 3D asset library virtual model.

The scene construction submodule is connected to the semantic similarity determining submodule, and configured to construct a digital cousin scene by Unity3d engine.

The matching submodule is connected to the scene construction submodule, and configured to perform digital cousin matching in the digital cousin scene according to the point cloud data and the semantic similarity to obtain the digital cousin scene information.

An embodiment of the present disclosure further provides a method for action-level planning of a coal mine robot based on digital cousin and MR, which is implemented by adopting the apparatus for action-level planning of a coal mine robot based on digital cousin and MR. The method for action-level planning of a coal mine robot based on digital cousin and MR includes the following steps.

Scene information data is acquired, where the scene information data includes single-frame RGB images collected from an underground coal mine.

Digital cousin scene information is determined, where the digital cousin scene information is determined according to the scene information data based on a 3D asset library virtual model; the 3D asset library virtual model is a preset model library which covers operational objects, operational tools, a terrain structure, mechanical devices and auxiliary devices, and faces an operation task of the underground coal mine.

As an alternative embodiment, digital cousin scene information is specifically determined as follows:

The scene information data is subjected to semantic segmentation to obtain segmented information data; the segmented information data is subjected to object label annotation by a large language model to obtain annotation information, and point cloud data, which includes three-dimensional position information, is determined according to the annotation information.

Semantic similarity is determined according to the annotation information and the 3D asset library virtual model; a digital cousin scene is constructed using Unity3d engine; and digital cousin matching is performed in the digital cousin scene according to the point cloud data and the semantic similarity to obtain the digital cousin scene information.

The digital cousin scene information is input into the imitation learning model to obtain action data. The action data includes motion pose information of the coal mine robot, and operation pose information of a robotic arm, the imitation learning model is obtained by performing simulation training and zero-shot transfer on a coal mine robot behavior model, the coal mine robot behavior model is obtained by performing reinforcement learning and simulation training on the coal mine robot model, and the coal mine robot model is a physical model constructed by a 3D modeling tool based on entity parameters of the coal mine robot, where the entity parameters include a size proportion, structure data and shape data.

The coal mine robot behavior model is performed as follows:

Task data is acquired, where the task data is operation data of the coal mine robot when executing the task; a reinforcement learning simulation environment is constructed by ML-Agents toolkit; the task data is subjected to task decomposition to obtain basic behavior data, where the basic behavior data includes operation data corresponding to movement, rotation, grabbing, and placement; and based on the set reinforcement learning reward and punishment mechanism, the coal mine robot model is subjected to multi-task optimization training according to the basic behavior data in the reinforcement learning simulation environment by a reinforcement learning algorithm to obtain the coal mine robot behavior model.

As an alternative embodiment, the imitation learning model is determined as follows:

A demonstration dataset is acquired, where the demonstration dataset includes state, action and reward data of the coal mine robot behavior model at different scenes; the demonstration dataset is filtered to obtain filtered data; domain randomization is added in Unity3d based on the filtered data and the coal mine robot behavior model to perform simulation training, and the trained model is transferred to the coal mine robot to obtain the imitation learning model, where the domain randomization includes randomly changing illumination, color of objects, friction coefficients of the objects.

An action pre-planning result is determined according to the action data.

The action pre-planning result is adjusted by a multimodal interaction method to obtain an adjusted planning result.

In an embodiment, the action pre-planning result is adjusted by a multimodal interaction method to obtain an adjusted planning result as follows:

The action pre-planning result is subjected to interference analysis through a mixed reality head-mounted display to determine whether to adjust the action pre-planning result to obtain a determination result.

If the determination result is yes, passing points are selected from a space of the action pre-planning result by gaze interaction in the multimodal interaction as movement path points.

The action pre-planning result is subjected to interpolation marking based on gesture interaction in the multimodal interaction to determine key points of trajectory tuning of the robotic arm to obtain trajectory adjusting points of the robotic arm.

Action tuning is confirmed according to the movement path points and the trajectory adjusting points of the robotic arm based on voice interaction in the multimodal interaction to obtain the adjusted planning result.

The adjusted planning result is processed by a preset action planning algorithm, and subjected to spatiotemporal deduction according to the time dimension to obtain a spatiotemporal deduction result. The spatiotemporal deduction result includes a movement path of the coal mine robot and a movement trajectory of the robotic arm. The preset action planning algorithm includes: A* algorithm and Rapidly-exploring Random Tree-Connect (RRT-Connect) algorithm. The A* algorithm is configured to determine the movement path of the coal mine robot, and the RRT-Connect algorithm is configured to determine the movement trajectory of the robotic arm.

In an embodiment, the adjusted planning result is processed by a preset action planning algorithm, and spatiotemporal deduction is performed according to the time dimension to obtain a spatiotemporal deduction result as follows:

The adjusted planning result is tuned by the preset action planning algorithm to obtain an action tuning result, and the spatiotemporal deduction is performed according to the time dimension based on the action tuning result to obtain the spatiotemporal deduction result.

An action planning result is determined according to the spatiotemporal deduction result, where the action planning result includes position coordinates, pose information, and path points.

The action planning result is determined according to the spatiotemporal deduction result as follows:

It is determined whether expected action information is met or not according to the spatiotemporal deduction result; if the expected action information is met, the spatiotemporal deduction result is subjected to data conversion according to a preset standard instruction format to obtain converted data, and the action planning result is determined according to the converted data.

The present disclosure further provides an application scene, which utilizes the method for action-level planning of a coal mine robot based on digital cousin and MR. Specifically, the method for action-level planning of a coal mine robot based on digital cousin and MR provided by this embodiment can be applied to the transportation scene of the underground coal mine. The transportation scene of the underground coal mine includes an information acquisition link, an action planning link, and a transportation execution link. The environmental information (scene information) collected from the underground coal mine enters the action planning link from the information acquisition link, and in the action planning link, action pre-planning of the coal mine robot is achieved by performing reinforcement learning and imitation learning under the digital cousin environment, and the pre-planning result is tuned to obtain a corresponding action planning result. Then, the robot enters the downstream transportation execution link and moves according to the action planning result to achieve the transportation operation in the underground coal mine. The method for action-level planning of a coal mine robot based on digital cousin and MR provided by this embodiment belongs to the process of action pre-planning, adjustment, and deduction of tuning in the action planning link.

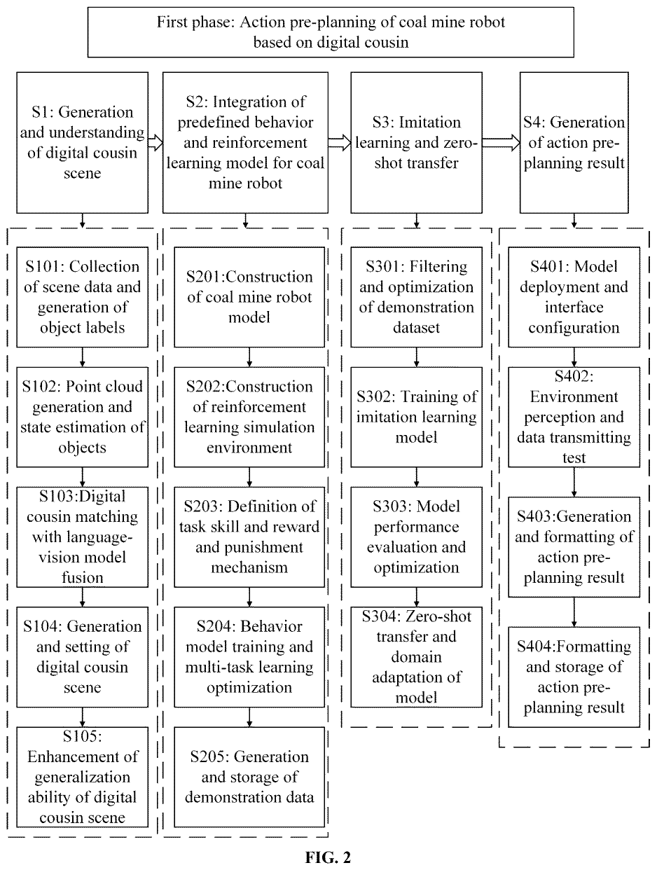

As shown in FIG. 2, the technical concept of the method adopted by the present disclosure mainly includes two phases: action pre-planning of the coal mine robot based on digital cousin and action tuning of the coal mine robot based on mixed reality.

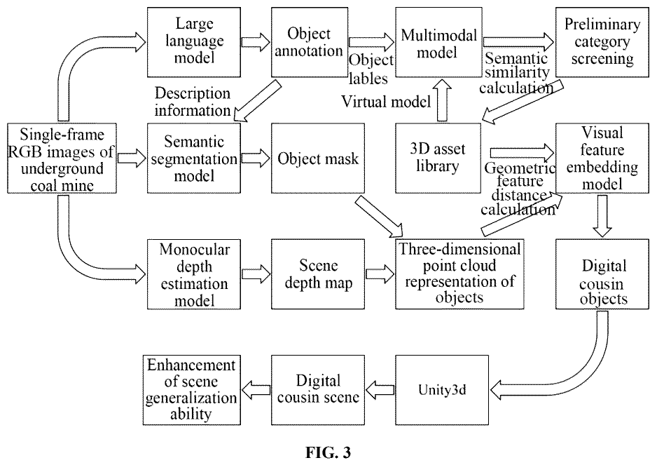

The action pre-planning phase of the coal mine robot based on the digital cousin includes the following steps S1 to S4.
S1: Generation and understanding of digital cousin scene, with the principle shown in FIG. 3.
S101: Collection of scene data, i.e., scene information data, and generation of object labels. Single-frame RGB images are collected from a real underground coal mine scene, a pre-trained semantic segmentation model is configured to generate masks of objects related to an operational task in the images. A large language model is adopted to annotate objects in the images one by one, and transmit description information to the semantic segmentation model to ensure that each object has a unique label.

The semantic segmentation model is Grounded Segment Anything Model 2 (Grounded SAM2), which can identify and segment a complex object by combining language and vision input, and is suitable for semantic segmentation under a complex scene. The large language model is Generative Pre-trained Transformer 4 omni (GPT-4o), which inherits the core competence of GPT-4 and has more advantages in speed and cost.
S102: Point cloud generation and state estimation of objects. A monocular depth estimation model is configured to generate a depth map of the scene to obtain three-dimensional position information of each object. The depth map is converted into point cloud data, and the point cloud data is combined with mask information of the objects to generate a three-dimensional point cloud representation of each object. The poses and sizes of the objects are estimated according to the point cloud data to prepare for the matching and placement of subsequent virtual objects.

The monocular depth estimation model is Depth Anything V2, which can capture the changes of hierarchy and depth more accurately in comparison with other depth estimation models.
S103: Digital cousin matching with language-vision model fusion. The semantic similarity between the actual object labels (annotation information) and the virtual model in the 3D asset library is calculated through a multimodal model to complete preliminary category screening of the 3D asset library. A geometric feature distance between each actual object and the virtual model is calculated by using a visual feature embedding model, that is, the semantic similarity is determined according to the annotation information and the virtual model of the 3D asset library, and virtual objects with the closest shapes and semantic are selected as digital cousin objects.

The 3D asset library is a preestablished model library which faces an underground operational task of the coal mine and covers operational objects, operational tools, a terrain structure, mechanical devices and auxiliary devices.

The multimodal model is Contrastive Language-Image Pre-training (CLIP), which has the ability to understand text description and establish association with visual information. The visual feature embedding model is DINOv2, which has high-quality visual feature embedding ability and can accurately capture the geometric and semantic features of the objects.
S104: Generation and setting of digital cousin scene. Unity3d engine is adopted to create a digital cousin scene, a corresponding digital cousin object is placed in the corresponding position in the scene according to the depth information and spatial position of each object, and the size of the object is adjusted to match the real size. Appropriate physical properties are set for the digital cousin objects in the scene to ensure that the digital cousin objects can be consistent with the physical behavior of the actual objects. That is, digital cousin matching is carried out in the digital cousin scene according to the point cloud data and semantic similarity to obtain the digital cousin scene information.

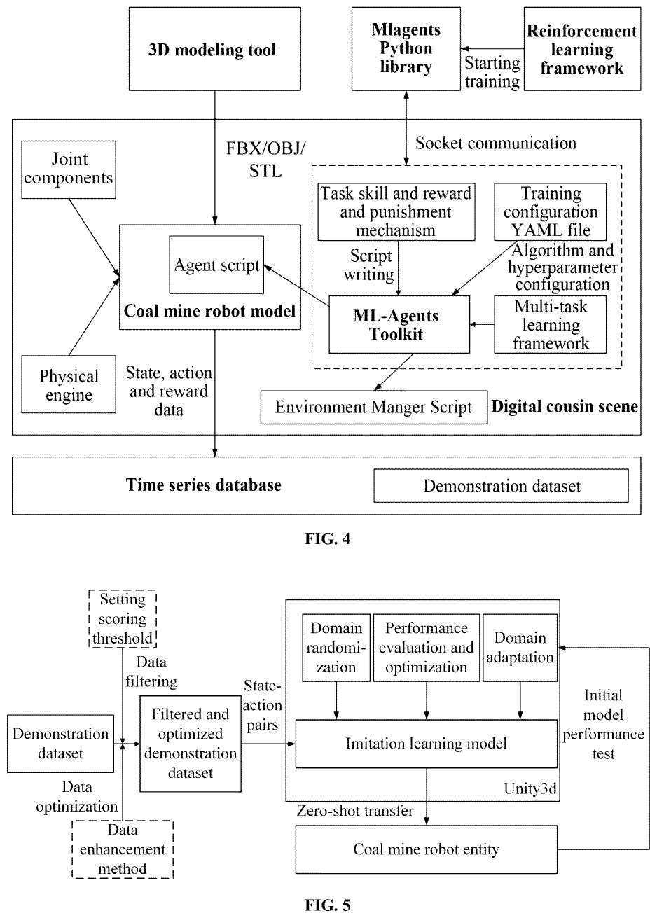

The setting of the physical attributes is achieved by rigid bodies, colliders, and joint components in Unity3d engine.
S105: Enhancement of generalization ability of digital cousin scene. Shader and a material library of Unity3d engine are configured to randomize the appearance of the objects to improve the visual generalization ability of the robot. The positions and sizes of the objects are randomized in Unity3d engine to improve the task adaptability of the robot in different layouts and positions. Random obstacles or dynamic elements are added to Unity3d to further enhance the diversity of the scene.
S2: Integration of predefined behavior and reinforcement learning model for coal mine robot, with the principle shown in FIG. 4.
S201: Construction of coal mine robot model. A 3D modeling tool is adopted to create a coal mine robot model, and it is ensured that the size proportion, structure and shape of the model are completely consistent with the physical entity of the coal mine robot, and the model is integrated into the digital cousin scene. The joint components of Unity3d engine are used to control the rotation and movement range of each moving part of the coal mine robot model, and a physical engine is added to the coal mine robot model to ensure that the coal mine robot model conforms to the actual motion law.

The 3D modeling tool is Blender, which integrates the modeling and rendering flows, supports FBX, OBJ and STL formats, and is convenient for seamless integration with Utility 3d.

The joint components include Configurable Joint, Hinge Joint, Fixed Joint and Spring Joint, where Configurable Joint is configured to control complex translation and rotation of a coal mine robot base, Hinge Joint is configured to control the rotation of a robotic arm joint, Fixed Joint is configured to fix the base and a base of the robotic arm, and Spring Joint is configured to control the grasping of an end effector of the robotic arm.
S202: Construction of reinforcement learning simulation environment. ML-Agents toolkit is installed and configured, and the core scripts are mounted for the coal mine robot model and the digital cousin environment. In training configuration YAML file, an appropriate reinforcement learning algorithm is selected, and the hyperparameters are set. Socket communication between mlagents Python library and Unity3d is established to achieve real-time data interaction between Python-side training and Unity3d simulation environment.

The core scripts include Agent scripts and Environment Manager scripts, where the Agent scripts are mounted on the robot model and responsible for the behavior and learning of the robot model, and Environment Manager scripts are mounted in the digital cousin environment and responsible for the management and coordination of the overall environment.

The reinforcement learning algorithm is a deep deterministic policy gradient (DDPG) algorithm, which is suitable for a continuous action space and has good effect in robot training.

S203: Definition of task skill and reward and punishment mechanism. The complex task of the coal mine robot is decomposed into basic behaviors. A reinforcement learning reward and punishment mechanism is set for each behavior and written in the form of code into the OnActionReceived ( ) method. OnActionReceived ( ) method is called in the AddReward ( ) or EndEpisode ( ) method, making the robot get corresponding feedback upon each success or failure. The basic behaviors include movement, rotation, grabbing, and placement.

The reinforcement learning reward and punishment mechanism specifically includes: rewarding a coal mine robot agent when the coal mine robot agent successfully completes its behavior, and punishing the coal mine robot agent when the coal mine robot agent fails to complete the behavior or collides with an obstacle.
S204: Behavior model training and multi-task learning optimization. A reinforcement learning framework is adopted to start training to constantly optimize the policy of each behavior model through repeated execution and reward feedback. Under the multi-task learning framework, a scheduling mechanism is configured to switch between different behaviors to ensure that the reinforcement learning model achieves good policy optimization effect on each behavior task. The reinforcement learning framework is TensorFlow or PyTorch.
S205: Generation and storage of demonstration data. The trained model policy is run in the simulation environment, the coal mine robot model is put in a diversified scene, the state, action and reward data in each scene are recorded to generate a complete demonstration dataset. The generated dataset is structurally stored in the database to ensure that the demonstration data can be directly accessed and used in subsequent imitation learning or training adjustment.

The database is InfluxDB, which belongs to a time series database, can handle mass time stamp data, and is suitable for the continuous data stream generated by the robot agent during training.
S3: Imitation learning and zero-shot transfer, with the principle shown in FIG. 5.
S301: Filtering and optimization of demonstration dataset. In the demonstration dataset, a task completion rate, a path length, motion smoothness and task completion time are weighted and scored, a scoring threshold is set and only data higher than the threshold is retained. A data enhancement method is adopted to optimize the demonstration data, including adding different environmental conditions or position changes, to ensure that the data covers more scenes and boundary conditions and improve the generalization ability of the model.
S302: Training of imitation learning model. The filtered and optimized demonstration dataset, i.e., the filtered data, is used to train the robot imitation learning model in Unity3d, state-action pairs are input into the imitation learning model to learn how to imitate the operation in the demonstration data. Domain randomization is added in the simulation training to make the model adapt to more extensive physical and visual conditions, thus improving the robustness of the imitation learning model in the actual environment. That is, based on the filtered data and the coal mine robot behavior model, the domain randomization is added in Unity3d to perform simulation training. The domain randomization includes randomly changing illumination, colors of objects, friction coefficients of the objects.
S303: Model performance evaluation and optimization. The performance of the model in the simulation environment is tested to ensure that the tasks can be accurately carried out under different conditions, and it is focused on evaluating the adaptability of the model in a field randomization environment. According to the test results, the model is fine-tuned to ensure its stability in key task steps and changing environment, thus further optimizing the generalization effect of the model.
S304: Zero-shot transfer and domain adaptation of model. The model after simulation training is directly transferred to the coal mine robot entity, and the initial performance of the model is directly tested without additional real environment training. The trained model is transferred to the coal mine robot to obtain the imitation learning model. During transferring, the performance of the model in the actual environment is observed. If there is a deviation, domain adaptation can be used to make adaptive adjustment on the model.
S4: Generation of action pre-planning result. S401: Model deployment and interface configuration. The trained imitation learning model is loaded and deployed to an upper computer of the coal mine robot to make the model run in the actual environment. An appropriate communication protocol is selected to configure a communication interface between the upper computer of the robot and the imitation learning model to ensure that the robot can acquire an instruction generated by the model in real time. The communication protocol is ROS.
S402: Environment perception and data transmitting test. A coal mine robot sensor system is started and initialized to ensure that the robot can obtain environmental information in real time, thus providing accurate environmental data for subsequent action planning. The data transmission test is carried out before the actual task to ensure that the model can receive the sensor data of the coal mine robot and output a corresponding action planning result.

The coal mine robot sensor system includes an IMU (Inertial Measurement Unit), a three-dimensional lidar, a depth camera, and a visible light camera.
S403: Generation and formatting of action pre-planning result. According to the input operational task objective and the perception of the coal mine robot for the operational objects, the tools and the environmental conditions, a complete movement path and a robotic arm trajectory required by the coal mine robot to complete the operational task are generated based on the imitation learning model, and a series of action data are output, including the position and pose information of the coal mine robot motion and robotic arm operation.
S404: Formatting and storage of action pre-planning result. The action data are organized into an array, in which each node includes position coordinates, a direction angle, a time stamp and other auxiliary information. The action data in the form of array is saved as a JSON file to a specific location for transmission to the mixed reality program in the subsequent action tuning phase.

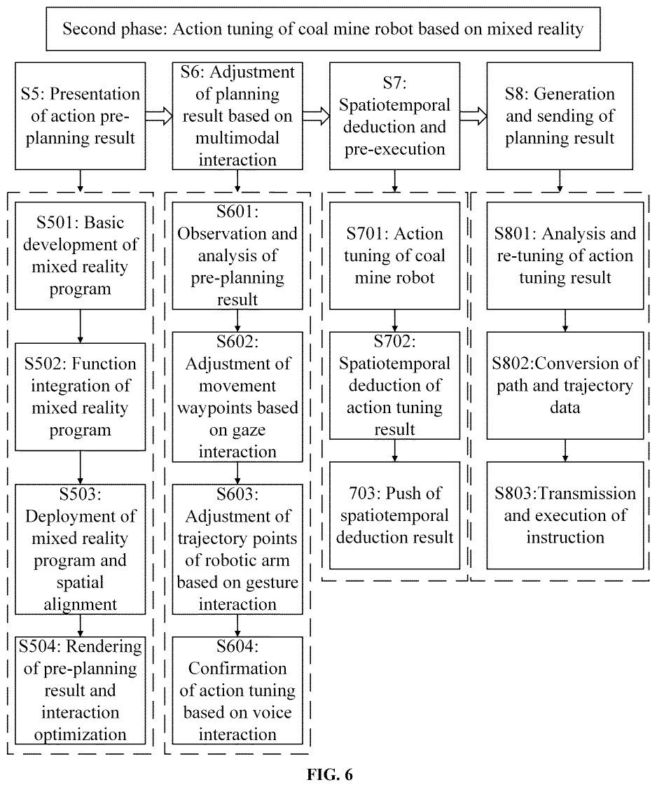

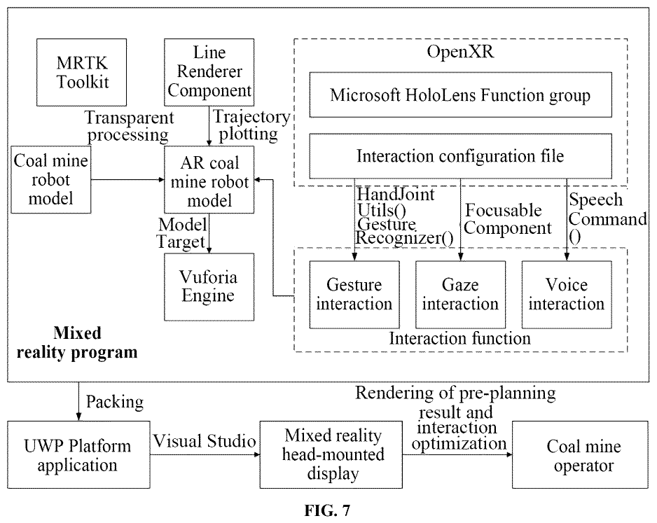

As shown in FIG. 6, the action tuning phase of a coal mine robot based on mixed reality includes the following steps S5 to S8.
S5: Presentation of action pre-planning result, with principle shown in FIG. 7.
S501: Basic development of mixed reality program. MRTK toolkit is introduced and configured in Unity3d engine, OpenXR is selected as XY development plug-ins, and Microsoft HoloLens functional group is added. The coal mine robot model constructed in S201 is introduced into the scene, and modified into a coal mine robot AR model made of a translucent material to ensure the fusion effect of the mixed reality program.
S502: Function integration of mixed reality program. Gesture interaction, gaze interaction and voice interaction functions are added through an interaction configuration file of OpenXR, thus enabling a coal mine operator to tune the action planning result later. Vuforia Engine is introduced into the mixed reality program, and the coal mine robot model is taken as Model Target; Line Renderer component is integrated for the coal mine robot AR model to support the plotting of the action trajectory.

The gesture interaction is configured to detect the gesture by HandJointUtils( ) and GestureRecognizer( ) classes.

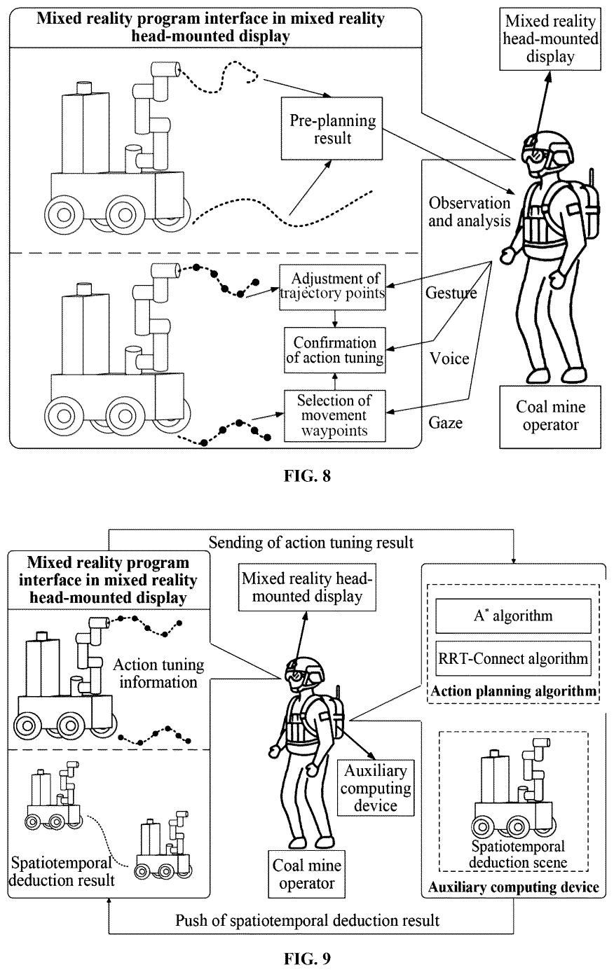

The gaze interaction enables the object to respond to the gaze through the Focusable component. The voice interaction is configured to define a recognizable voice command by SpeechCommand( ) class.
S503: Deployment of mixed reality program and spatial alignment. The developed mixed reality program is packed and generated as UWP platform application, which is deployed to the mixed reality head-mounted display through Visual Studio, and the mixed reality head-mounted display is worn by the coal mine operator. When the physical entity of the coal mine robot is detected in the field of view of the mixed reality head-mounted display, Model Target is loaded, and the poses of the coal mine robot model and the physical entity of the coal mine robot are accurately overlapped. The mixed reality head-mounted display is Microsoft HoloLens2.
S504: Rendering of pre-planning result and interaction optimization. The action data in JSON format stored in S404 is loaded into the mixed reality program, Line Renderer component is adopted to plot pre-planning results of the movement path of the coal mine robot and the trajectory of the robotic arm, and interpolation points are marked at key positions. Manipulation Handler component is added for the object at each interpolation point to make the object have the ability to be dragged through gesture interaction.
S6: Adjustment of planning result based on multimodal interaction, with the principle shown in FIG. 8.
S601: Observation and analysis of pre-planning result. The coal mine operator observes the plotted action pre-planning result of the coal mine robot through the mixed reality head-mounted display, and determines whether the coal mine robot can accurately execute the operational task according to the planning result, and whether the movement path and the robotic arm interfere with the obstacles in the environment or the next behavior of the coal mine operator, thus analyzing whether the action pre-planning result needs to be adjusted and how to adjust the action pre-planning result.
S602: Selection of movement waypoints based on gaze interaction. The coal mine operator selects multiple key points in the space through gaze interaction as via points for the tuning of the movement path of the coal mine robot. To ensure the accuracy of point selection and avoid mis-operation, the system is designed to determine the point is selected when the line of sight of the coal mine operator stays at a certain target point for more than 3 seconds.
S603: Adjustment of trajectory points of robotic arm based on gesture interaction. The coal mine operator moves the interpolation points marked on the pre-planning result of the trajectory of the robotic arm through gesture interaction to serve as the key points for tuning of the trajectory of the robotic arm. When the coal mine operator adjusts the interpolation points, a workspace of the robotic arm is displayed in the mixed reality program to avoid adjusting the points to a position that the robotic arm cannot reach.
S604: Confirmation of action tuning based on voice interaction. After completing the selection of the movement waypoints of the coal mine robot and the adjustment of the trajectory points of the robotic arm, the coal mine operator gives a command for re-planning through a voice instruction. To avoid mistaken identification, reconfirmation by voice is required after the re-planning command is issued.
S7. Spatiotemporal deduction and pre-execution, with the principle shown in FIG. 9.
S701: Action tuning of coal mine robot model. The pose information of the movement waypoints of the coal mine robot and the trajectory points of the robotic arm after the setting and adjustment by the coal mine operation is recorded and transmitted to an auxiliary computing device, the trajectory is re-planned by the preset action planning algorithm deployed in the auxiliary computing device, and the re-planning result is presented in the mixed reality head-mounted display.

The auxiliary computing device is an embedded edge computing box, which is placed in an explosion-proof shell and can be carried by the coal mine operator in a piggyback way. The preset action planning algorithm is a combination of A* algorithm and RRT-Connect algorithm. The A* algorithm is used for movement path planning, and the RRT-Connect algorithm is used for trajectory planning of the robotic arm.

Further, the communication protocol between the auxiliary computing device and the mixed reality head-mounted display is Socket.
S702: Spatiotemporal deduction of action tuning result. Spatiotemporal deduction is carried out in the auxiliary computing device according to an action tuning result of the coal mine robot, that is, the motion processes of the coal mine robot base and the robotic arm are gradually pre-executed according to the time dimension in the spatiotemporal deduction scene.
S703: Push of spatiotemporal deduction result. The spatiotemporal deduction result is sent to the mixed reality program in the mixed reality head-mounted display to generate visual preview of the movement path of the coal mine robot and the trajectory of the robotic arm, thus displaying expected poses of the coal mine robot and the robotic arm at each moment.
S8: Generation and sending of planning result.
S801: Analysis and re-tuning of action tuning result. The coal mine operator determines whether the action tuning result is reasonable and feasible and whether there is an unexpected action according to the spatiotemporal deduction result in the mixed reality head-mounted display. If it is still necessary to continue to adjust the action tuning result, the coal mine operator can cyclically execute S602-S703 until the path fully meets the requirements before execution.
S802: Conversion of path and trajectory data. The ultimately confirmed data of the movement path of the coal mine robot and the trajectory of the robotic arm, i.e., the action planning result, including position coordinates, pose information and key path points, are derived from the mixed display program, and converted into an instruction format that meets the analytical standards of a robot control system.
S803: Transmission and execution of instructions. The data of the movement path of the coal mine robot and the trajectory of the robotic arm after formatting processing, i.e., the action planning results, are transmitted to the robot control system through a configured communication interface, and further analyzed into movement instructions of the robot base and fine operation instructions of the robotic arm, thus ensuring that the robot can accurately and efficiently complete the operational task according to the action planning result and task requirements.

The present disclosure has the following beneficial effects:
(1) The action-level planning of the coal mine robot is divided into two phases: action pre-planning of the coal mine robot and action tuning of the coal mine robot. In the first phase, the action pre-planning of the coal mine robot is achieved through reinforcement learning and imitation learning in the digital cousin environment, and in the second phase, the coal mine operator can further optimize the pre-planning result with mixed reality as the interface on the basis of the previous phase, which not only makes full use of the global calculation and macro-planning capabilities of machine intelligence, but also embodies the flexible response and local optimization advantages of human intelligence.
(2) In the action pre-planning phase of the coal mine robot, the concept of digital cousin is introduced to extend the data of physical space to the simulation environment for learning. Compared with digital twins, the digital cousin, instead of pursuing the perfect reconstruction of the physical space in all tiny details, focuses on retaining higher-level details, such as the spatial relation and semantic information between the objects, which not only greatly reduces the generation of the virtual environment, but also helps to improve the cross-domain generalization ability of the learning strategies.
(3) The reinforcement learning algorithm is configured to establish the pre-planning model of the coal mine robot in the digital cousin environment, which can take the states of the coal mine robot base and the robotic arm as a joint state space for joint action planning, and enhance the task adaptability and universality of the pre-planning model while simplifying the action planning process. In addition, effective action planning can be achieved through interaction training, thus omitting complicated kinematics analysis and modeling process, and improving the planning efficiency.
(4) The mixed reality technology is taken as an interface and channel for the coal mine operator to deeply participate in the action planning of the coal mine robot, and its characteristics of virtual and real integration and its good support for multimodal interaction are fully utilized to enhance the active role of humans in the action planning of the coal mine robot, and the human-robot dynamic interaction and feedback in the human-robot collaborative planning are enhanced, enabling human-robot to make the final action planning result of the coal mine robot more flexible and reliable in the complex and dynamic underground coal mine environment.
(5) In the action tuning of the coal mine robot based on the mixed reality, the auxiliary computing device carried by the coal mine operator can be configured to perform spatiotemporal deduction on the action planning result tuned by the coal mine operator in the virtual scene, and present the deduction result intuitively in the mixed reality head-mounted display, which accords with the intuition of the coal mine operator, reduces the understanding cost of the coal mine operator and enables the coal mine operator to better concentrate on the action tuning process. In addition, the deployment position of the auxiliary computing device can reduce communication delay and speed up the planning process.

The technical features of the above embodiments can be combined at will. To make the description concise, not all possible combinations of the technical features in the above embodiments are described. However, it should be considered that these combinations of technical features fall within the scope recorded in this specification provided that these combinations of technical features do not have any conflicts.

Specific examples are used herein for illustration of the principles and embodiments of the present disclosure. The description of the embodiments is merely used to help illustrate the method and its core principles of the present disclosure. In addition, a person of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. An apparatus for action-level planning of a coal mine robot based on digital cousin and MR (Mixed Reality), comprising:
an information data acquisition module, configured to acquire scene information data, wherein the scene information data comprises single-frame red, green, and blue (RGB) images collected from an underground coal mine;
a digital cousin scene information determining module, connected to the information data acquisition module, and configured to determine digital cousin scene information, wherein the digital cousin scene information is determined according to the scene information data based on a 3D asset library virtual model, and the 3D asset library virtual model is a preset model library, wherein the preset model library covers operational objects, operational tools, a terrain structure, mechanical devices and auxiliary devices, and faces an operation task of the underground coal mine;
an action data determining module, connected to the digital cousin scene information determining module, and configured to input the digital cousin scene information to an imitation learning model to obtain action data, wherein the action data comprises motion pose information of the coal mine robot and operation pose information of a robotic arm, the imitation learning model is obtained by performing simulation training and zero-shot transfer based on a coal mine robot behavior model, the coal mine robot behavior model is obtained by performing reinforcement learning and simulation training on a coal mine robot model, and the coal mine robot model is a physical model constructed by a three-dimensional (3D) modeling tool based on entity parameters of the coal mine robot, wherein the entity parameters comprise: a size proportion, structure data and shape data;
an action pre-planning module, connected to the action data determining module, and configured to determine an action pre-planning result according to the action data;
an adjusting module, connected to the action pre-planning module, and configured to adjust the action pre-planning result by a multimodal interaction method to obtain an adjusted planning result;
a spatiotemporal deduction module, connected to the adjusting module, and configured to process the adjusted planning result by a preset action planning algorithm, and perform spatiotemporal deduction according to a time dimension to obtain a spatiotemporal deduction result, wherein the spatiotemporal deduction result comprises a movement path of the coal mine robot and a movement trajectory of the robotic arm; and
an action planning module, connected to the spatiotemporal deduction module, and configured to determine an action planning result according to the spatiotemporal deduction result, wherein the action planning result comprises position coordinates, pose information, and path points.

2. The apparatus according to claim 1, wherein the digital cousin scene information determining module comprises:
a semantic segmentation submodule, connected to the information data acquisition module, and configured to perform semantic segmentation on the scene information data to obtain segmented information data;
a label annotation submodule, connected to the semantic segmentation submodule, and configured to perform object label annotation on the segmented information data by a large language model to obtain annotation information;
a point cloud data determining submodule, connected to the label annotation submodule, and configured to determine point cloud data according to the annotation information, wherein the point cloud data comprises three-dimensional position information;
a semantic similarity determining submodule, connected to the point cloud data determining submodule, and configured to determine semantic similarity according to the annotation information and the 3D asset library virtual model;
a scene construction submodule, connected to the semantic similarity determining submodule, and configured to construct a digital cousin scene by Unity3d engine; and
a matching submodule, connected to the scene construction submodule, and configured to perform digital cousin matching in the digital cousin scene according to the point cloud data and the semantic similarity to obtain the digital cousin scene information.

3. A method for action-level planning of a coal mine robot based on digital cousin and MR, wherein the method is implemented using the apparatus according to claim 1, and comprises:
acquiring the scene information data, wherein the scene information data comprises the single-frame RGB images collected from the underground coal mine;
determining the digital cousin scene information, wherein the digital cousin scene information is determined according to the scene information data based on the 3D asset library virtual model, and the 3D asset library virtual model is the preset model library, wherein the preset model library covers the operational objects, the operational tools, the terrain structure, the mechanical devices and the auxiliary devices, and faces the operation task of the underground coal mine;
inputting the digital cousin scene information to the imitation learning model to obtain the action data, wherein the action data comprises the motion pose information of the coal mine robot and the operation pose information of the robotic arm, the imitation learning model is obtained by performing simulation training and zero-shot transfer based on the coal mine robot behavior model, the coal mine robot behavior model is obtained by performing reinforcement learning and simulation training on the coal mine robot model, and the coal mine robot model is the physical model constructed by the 3D modeling tool based on the entity parameters of the coal mine robot, wherein the entity parameters comprise: the size proportion, the structure data and the shape data;
determining the action pre-planning result according to the action data;
adjusting the action pre-planning result by the multimodal interaction method to obtain the adjusted planning result;
processing the adjusted planning result by the preset action planning algorithm, and performing spatiotemporal deduction according to the time dimension to obtain the spatiotemporal deduction result, wherein the spatiotemporal deduction result comprises the movement path of the coal mine robot and the movement trajectory of the robotic arm; and
determining the action planning result according to the spatiotemporal deduction result, wherein the action planning result comprises the position coordinates, the pose information, and the path points.

4. The method according to claim 3, wherein determining the digital cousin scene information comprises:
performing semantic segmentation on the scene information data to obtain segmented information data;
performing object label annotation on the segmented information data by a large language model to obtain annotation information;
determining point cloud data according to the annotation information, wherein the point cloud data comprises three-dimensional position information;
determining semantic similarity according to the annotation information and the 3D asset library virtual model;
constructing a digital cousin scene by Unity3d engine; and
performing digital cousin matching in the digital cousin scene according to the point cloud data and the semantic similarity to obtain the digital cousin scene information.

5. The method according to claim 3, wherein adjusting the action pre-planning result by the multimodal interaction method to obtain the adjusted planning result comprises:
performing interference analysis on the action pre-planning result through a mixed reality head-mounted display, and determining whether to adjust the action pre-planning result to obtain a determination result;
when it is determined to adjust the action pre-planning result, selecting via points from a space of the action pre-planning result by gaze interaction in multimodal interaction as movement path points;
performing interpolation marking on the action pre-planning result based on gesture interaction in the multimodal interaction to determine key points of trajectory tuning of the robotic arm to obtain trajectory adjusting points of the robotic arm; and
confirming action tuning according to the movement path points and the trajectory adjusting points of the robotic arm based on voice interaction in the multimodal interaction to obtain the adjusted planning result.

6. The method according to claim 3, wherein processing the adjusted planning result by the preset action planning algorithm, and performing spatiotemporal deduction according to the time dimension to obtain the spatiotemporal deduction result comprise:
performing tuning on the adjusted planning result by the preset action planning algorithm to obtain an action tuning result; and
performing spatiotemporal deduction based on the time dimension according to the action tuning result to obtain the spatiotemporal deduction result.

7. The method according to claim 3, wherein determining the action planning result according to the spatiotemporal deduction result comprises:
determining whether expected action information is met or not according to the spatiotemporal deduction result;
when the expected action information is met, performing data conversion on the spatiotemporal deduction result according to a preset standard instruction format to obtain converted data; and
determining the action planning result according to the converted data.

8. The method according to claim 3, wherein a determining method of the coal mine robot behavior model comprises:
acquiring task data, wherein the task data is operation data of the coal mine robot when executing a task;
constructing a reinforcement learning imitation environment by an ML-Agents toolkit;
performing task decomposition on the task data to obtain basic behavior data, wherein the basic behavior data comprises operation data corresponding to movement, rotation, grabbing, and placement; and
performing multi-task optimization training on the coal mine robot model according to the basic behavior data in a reinforcement learning simulation environment based on a set reinforcement learning reward and punishment mechanism by a reinforcement learning algorithm to obtain the coal mine robot behavior model.

9. The method according to claim 3, wherein a determining method of the imitation learning model comprises:
acquiring a demonstration dataset, wherein the demonstration dataset is state, action and reward data of the coal mine robot behavior model in different scenes;
filtering the demonstration dataset to obtain filtered data; and
adding domain randomization in Unity3d based on the filtered data and the coal mine robot behavior model to perform simulation training to obtain a trained model, and transferring the trained model to the coal mine robot to obtain the imitation learning model, wherein the domain randomization comprises randomly changing illumination, colors of objects, and friction coefficients of the objects.

10. The method according to claim 3, wherein the preset action planning algorithm comprises: A* algorithm and RRT (Rapidly-exploring Random Tree)-Connect algorithm; wherein the A* algorithm is configured to determine the movement path of the coal mine robot, and the RRT-Connect algorithm is configured to determine the movement trajectory of the robotic arm.
